(19) United States
(12) Patent Application Publication
(10) Pub. No.: US 2008/0217739 A1
(43) Pub. Date: Sep. 11, 2008

(54) Semiconductor packaging substrate structure with capacitor embedded therein

(75) Inventors: Chung-Cheng Lien, Hsin-feng (TW); Chih-Kui Yang, Hsin-feng (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/153,388

(22) Filed: May 19, 2008

(30) Foreign Application Priority Data
Dec. 22, 2006 (TW) 095148380

(51) Int. Cl. H01L 27/08

(52) U.S. Cl. 257/535; 257/E27.048

(57) ABSTRACT

The present invention relates to a semiconductor packaging substrate structure with a capacitor embedded therein, which includes an inner circuit board, a patterned buffer layer, a high dielectric material layer, and a patterned metal layer. The buffer layer is disposed on at least one surface of the inner circuit board to expose the inner electrode layer of the internal board. The high dielectric material layer is located on the buffer layer and the inner electrode layer. The metal layer is placed on the high dielectric material layer including an outer circuit layer capable of electrical connection to the inner circuit layer, and an outer electrode layer corresponding to the inner electrode layer to form a capacitor. Owing to the assistance of the buffer layer, the structure can enhance the transmission and the quality of the products.

### BACKGROUND OF THE INVENTION

1. Field of the Invention

The present invention relates to a semiconductor packaging substrate structure with a capacitor embedded therein, and especially, to a semiconductor packaging substrate structure with a capacitor embedded therein, which has improved performance as to capacitance.

2. Description of Related Art

Owing to the rapid progress in semiconductor processing technology, and the upgrading performance of semiconductor chips, the semiconductor devices move towards high integration. While semiconductor devices have become highly integrated, the number of pins in a packaging structure also has increased. However, owing to the increased number of pins and highly dense circuit layouts, noise interference in a packaging structure now becomes greater than it was before. As a result, the amount of applied passive components (such as resistors, capacitors, and inductors) disposed in a semiconductor packaging structure may be increased generally to eliminate noise or compensate the performance. If elimination of noise and stabilization of performance are achieved, the packaged semiconductor chip can meet the requirements of electrical performance of semiconductor chips.

In conventional methods, a capacitor is generally mounted on a package substrate by surface mount technology (SMT). Currently, capacitors are formed by laminating a high dielectric material layer between copper layers, and then proceeding formation of circuits. With reference to FIG. 1, a schematic cross-section of a capacitor formed by lamination is shown. As shown in FIG. 1, it includes an inner circuit board 11, a high dielectric material layer 12, an outer circuit layer 13, a plated through hole 14, a solder mask 15, and solder balls 16. The inner circuit board 11 has an inner circuit layer 11a. The high dielectric material layer 12 is laminated on the inner circuit layer 11a at first, and followed by forming the outer circuit layer 13 thereon during the manufacturing process. In addition, a portion of the outer circuit layer 13a corresponds to the inner circuit layer 11a so that a capacitor 17 is formed. The plated through hole 14 extends through the board and electrically connects the circuits on both sides of the board. Subsequently, the following process of forming the built-up structure is performed, and then the solder mask 15 and the solder balls 16 are formed on the outermost circuit layer of the built-up structure.

However, the method for using wholly covered high dielectric material layers for lamination is expensive, and only little part of the high dielectric material layer is used for forming a capacitor. Hence, great waste of the high dielectric material layer occurs in the conventional methods. Moreover, since the high dielectric material layer is filled with a large amount of ceramic material (60 vol % or more), it also results in poor fluidity of the high dielectric material. When the thickness of the circuits is increased, or the thickness of the high dielectric material layer is decreased, voids inevitably generate in the filling process and result in trouble. Furthermore, when the amount of the binder in the high dielectric material layer decreases, it may cause poor adhesion between the high dielectric material and the inner circuit layer. Besides, there are other problems in this method. For example, some high dielectric materials that are laminated between the circuit layers are not defined as electrodes for a capacitor, and could be wasted. As a result, parasitic capacitance occurs between the circuits of the same circuit layer, or those in two interlayer circuit layers, and further results in signaling interference such as current leakage, especially in the application at high frequency. In addition, both the compensation and accuracy of the capacitors made by the conventional method cannot be easily controlled.

### SUMMARY OF THE INVENTION

In view of the drawbacks in prior arts, the present invention provides a semiconductor packaging substrate comprising an inner circuit board, a patterned buffer layer, a high dielectric material layer, and a patterned metal layer. The inner circuit board has an inner circuit layer. The patterned buffer layer is disposed on at least one surface of the inner circuit board, wherein the portion of the inner circuit layer exposed by the patterned buffer layer serves as an inner electrode layer. Besides, the high dielectric material layer is located on the surfaces of the inner circuit board and the patterned buffer layer. The patterned metal layer, which comprises an outer circuit layer and an outer electrode layer, is placed on the surface of the high dielectric material layer, wherein the outer circuit layer electrically connects to the inner circuit layer of the inner circuit board, and the outer electrode layer locates corresponding to the inner electrode layer to form a capacitor.

According to the present invention, the above-mentioned semiconductor packaging substrate structure can be made, for example, by the following steps, but not limited thereto.

In the present invention, the semiconductor packaging substrate structure can further comprise at least one conductive via formed in the high dielectric material layer to electrically connect the outer circuit layer to the inner circuit layer. This conductive via can be or not be fully filled with conductive material.

The semiconductor packaging substrate structure of the present invention can further comprise an external plated through hole. The plated through hole extends through the inner circuit board, the buffer layer, and the high dielectric material layer to electrically connect the inner circuit layer to the outer circuit layer which is disposed on the surface of the high dielectric material layer formed on each of the surfaces of the inner circuit board.

In addition, the inner circuit board of the present invention can further comprise an internal plated through hole. The internal plated through hole can electrically connect the inner circuit layer on each of the surfaces of the inner circuit board. The inner circuit layer and the inner electrode layer in the inner circuit board are made of a material selected from the group consisting of Cu, Sn, Ni, Cr, Ti, Cu—Cr alloy, and Sn—Pb alloy.

In the present invention, the patterned buffer layer can be photoimagable resin, and preferably, be photoimagable resin with low coefficient of thermal expansion (CTE) and low dielectric constant (Dk). The opening of the buffer layer in the present invention is formed by photolithography. Compared to the high dielectric material layer, the buffer layer needs no filling with ceramic material, and thus has a better fluidity. Hence, the buffer layer can be deposited into the gap between the circuits, and patterned to form an opening (which is extremely larger than the gap between the circuits) exposing a portion of the inner circuit layer. The exposed portion of the inner circuit layer can serve as an electrode. As a result, the opening can be successfully filled with the high dielectric material layer so that the problem of uneven filling with the high dielectric material layer can be solved. Moreover, the opening can be formed in the buffer layer by photolithography, and thus the accuracy of the capacitor structure can be perfectly controlled.

The high dielectric material layer of the present invention can be composed of polymer material, ceramic material, polymer material filled with ceramic powders, or a mixture of the like thereof. Preferably, the high dielectric material layer can be formed by dispersing a material selected from the group consisting of barium titanate, lead zicronate tianate, and amorphous hydrogenated carbon into a binder. Besides, the high dielectric material layer can have a dielectric constant of 40 or more, and preferably in a range of from 40 to 300.

In the present invention, the metal layer for the outer circuit layer and the outer electrode layer can be made of a material selected from the group consisting of Cu, Sn, Ni, Cr, Ti, Cu—Cr alloy, and Sn—Pb alloy, but preferably be made of Cu.

In the present invention, after the above-mentioned semiconductor packaging substrate structure with a capacitor embedded therein is realized, the structure can further comprise a built-up structure which can be a single-layered or multi-layered structure. The built-up structure can be disposed on the surface of the outer circuit layer, and comprises a circuit layer and conductive vias. The conductive vias can electrically connect every circuit layer of the built-up structure, or connect to the outer circuit layer of the semiconductor packaging substrate structure in the present invention. Furthermore, the built-up structure of the present invention can further comprise a solder mask formed thereon. The solder mask can protect the semiconductor packaging substrate structure.

In the above-mentioned structure of the present invention, the capacitor can be formed in the double-layered or multi-layered inner circuit board. The capacitor can be formed in any layer of the inner circuit board. Besides, the capacitor is not limited to being single-layered but also can be multi-layered.

In conclusion, since the buffer layer is added in the semiconductor packaging substrate structure of the present invention, the adhesion of the circuit layer or the inner electrode layer can be improved so that current leakage occurring between the inner circuit layers can be avoided. Additionally, the gap between the inner circuit layers is filled with the buffer layer, and thus the conventional problem of poor filling can be solved. Also, the accuracy of the capacitor can be promoted in the structure of the present invention.

Other objects, advantages, and novel features of the invention will become more apparent from the following detailed description when taken in conjunction with the accompanying drawings.

### BRIEF DESCRIPTION OF THE DRAWINGS

FIG. 1 shows a cross-section of the conventional semiconductor packaging substrate structure with a laminated-capacitor embedded therein;

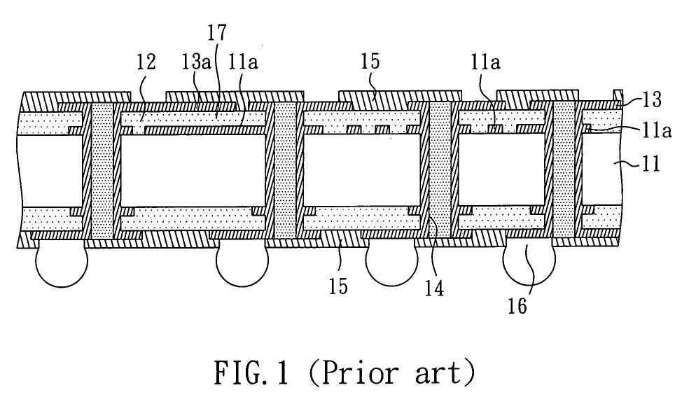

FIGS. 2A and 2E show a process in a cross-section for manufacturing the semiconductor packaging substrate structure with a capacitor embedded therein in Example 1 of the present invention;

FIGS. 3A and 3B show a process of manufacturing the semiconductor packaging substrate structure with a capacitor embedded therein in Example 2 of the present invention;

FIGS. 4A and 4B show a process in a cross-section for forming a built-up structure and solder balls on the semiconductor packaging substrate structure with a capacitor embedded therein in Example 3 of the present invention;

FIGS. 5A and 5B show a process of manufacturing the semiconductor packaging substrate structure with a capacitor embedded therein in Example 4 of the present invention; and

FIG. 6 shows a cross-section of the semiconductor packaging substrate structure with a capacitor embedded therein and with a built-up structure and solder balls formed thereon in Example 5 of the present invention.

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

### EXAMPLE 1

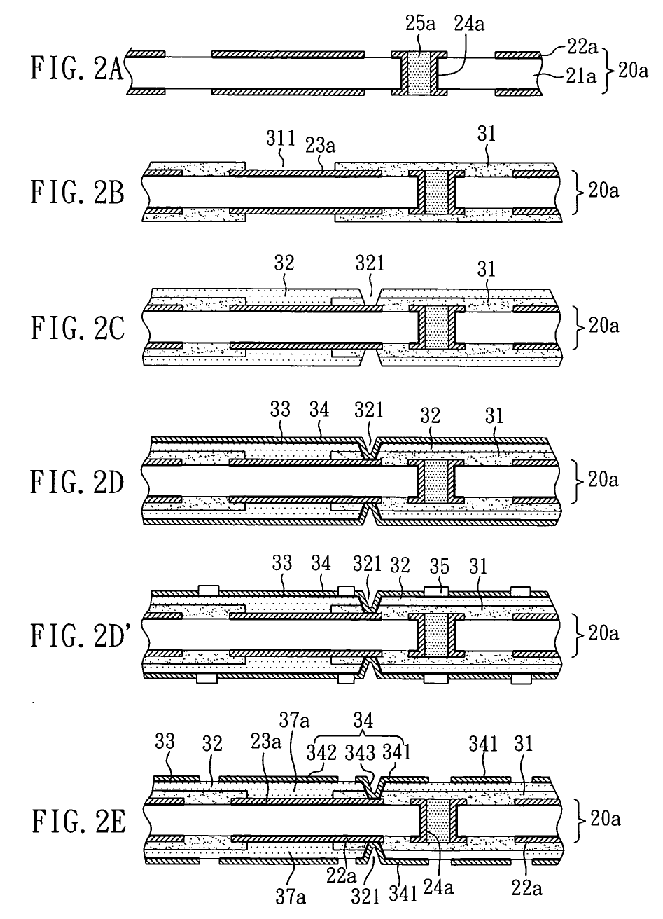

With reference to FIGS. 2A to 2E, there is a process in a cross-section for manufacturing the semiconductor packaging substrate structure with a capacitor embedded therein in the present invention.

As shown in FIG. 2A, an inner circuit board 20a is provided first in the present example. The inner circuit board 20a is made by forming an inner layer 22a on the surface of the carrier board 21a, followed by forming an internal plated through hole in the carrier board 21a through mechanical drilling and electroplating. This carrier board 21a can be made by any material. Besides, the internal plated through hole 24a is filled with an insulating resin 25a.

Subsequently, as shown in FIG. 2B, a patterned buffer layer 31 is formed on the surface of the inner circuit layer 20a by photolithography including exposure and development. The buffer layer 31 has an opening 311 formed therein, and the opening 311 exposes a portion of the inner circuit layer 22a serving as an inner electrode layer 23a. In the present example, the buffer layer 31 can be made of photoimagable resin.

In FIG. 2C, a high dielectric material layer 32 is formed on the surface of the inner circuit board 20a having the patterned buffer layer 31. The high dielectric material layer 32 can be made by dispersing a material selected from the group consisting of barium titanate, lead zicronate tianate, and amorphous hydrogenated carbon into a binder. For example, barium titanate can be dispersed in a binder to form the high dielectric material layer 32 in the present example. Besides, a via 321 is formed by laser drilling in the high dielectric material layer 32.

As shown in FIG. 2D, a seed layer 33 is formed by electroless plating on the high dielectric material layer 32 and in the via 321. A metal layer 34 is formed by electroplating on the seed layer 33. The metal layer 34 and the seed layer 33 can be made by a material selected from the group consisting of Cu, Sn, Ni, Cr, Ti, Cu—Cr alloy, and Sn—Pb alloy. In the present example, Cu is used. Finally, the metal layer 34 and the seed layer 33 covered thereby are etched to obtain a structure as shown in FIG. 2E, in which an outer circuit layer is formed on the high dielectric material layer, and an outer electrode layer is formed on the high dielectric material layer corresponding to the inner electrode layer 23a of the inner circuit board 20a. A conductive via 343 can be formed in the via 321, which is not fully filled with conductive material. The conductive material is the same as the material of the metal layer 34 in FIG. 2D. The conductive via 343 is used to electrically connect the outer circuit layer 341 to the inner circuit layer 22a. Hence, the semiconductor packaging substrate structure with a capacitor embedded therein can be obtained by the abovementioned method.

Besides, the present example can be illustrated as shown in FIG. 2D′. In FIG. 2D′, a seed layer 33 is formed by electroless plating on the surface of the high dielectric material layer 32 and in the via 321. Subsequently, a patterned resist layer 35 is formed on the surface of the seed layer 33. The resist layer 35 can be made of dry film or liquid photoresist. In the present example, dry film is used. Then, a metal layer 34 is formed by electroplating on the seed layer 33. The resist layer 35 and the seed layer 33 thereunder are removed to afford the semiconductor packaging substrate structure with a capacitor embedded therein as shown in FIG. 2E.

Accordingly, the semiconductor packaging substrate structure with a capacitor embedded therein of the present invention can be shown in FIG. 2E. The structure includes: an inner circuit board 20a, a patterned buffer layer 31, a high dielectric material layer 32, and a patterned metal layer 34. The inner circuit board 20a has an inner circuit layer 22a. The patterned buffer layer 31 is disposed on at least one surface of the inner circuit board 20a, wherein the portion of the inner circuit layer 22a exposed by the patterned buffer layer 31 serves as an inner electrode layer 23a. Besides, the high dielectric material layer 32 is located on the surfaces of the inner circuit board 20a and the patterned buffer layer 31. The patterned metal layer 34, which includes an outer circuit layer 341 and an outer electrode layer 342, is placed on the surface of the high dielectric material layer 32, wherein the outer circuit layer 342 electrically connects to the inner circuit layer 22a of the inner circuit board 20a, and the outer electrode layer 342 corresponds to the inner electrode layer 23a so that a capacitor 37a is formed. In the present example, the metal layer 34 further includes a conductive via 343 electrically connecting the outer circuit layer 341 to the inner circuit layer 22a.

### EXAMPLE 2

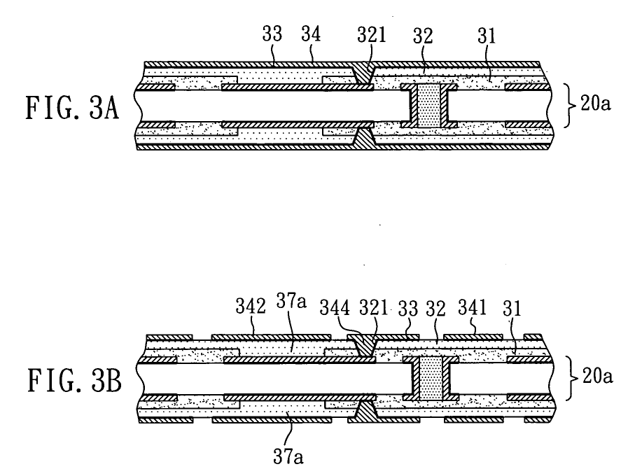

With reference to FIGS. 3A and 3B, there is a process in a cross-section for manufacturing the semiconductor packaging substrate structure with a capacitor embedded therein in the present invention. The present example is substantially similar to Example 1, except the via 321 is fully filled with conductive material. Finally, the semiconductor packaging substrate structure with a capacitor embedded therein, as shown in FIG. 3B, can be obtained by etching or the manner in FIG. 2D′. As a result, the conductive via 344 is formed by fully filling the via 321 with conductive material.

### EXAMPLE 3

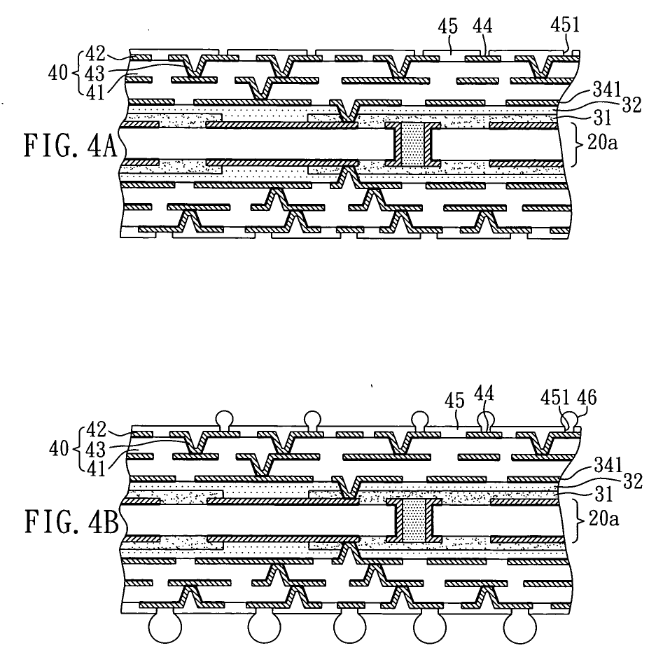

With reference to FIGS. 4A and 4B, a built-up structure in FIG. 4A can be formed on the surface of the semiconductor packaging substrate structure with a capacitor embedded therein manufactured in Example 1. As shown in FIG. 4A, the built-up structure includes a dielectric layer 41, a circuit layer 42, and a conductive via 43. Specifically, a resist layer (not shown in FIG. 4A) formed on the dielectric layer 41 is patterned by photolithography (including exposure and development), and then metal material such as Cu is deposited on the dielectric layer 41. After the resist layer is removed, the circuit layer 42 is formed. In addition, a via (not shown in FIG. 4A) is formed by laser ablation in the dielectric layer. While the metal material is deposited, the conductive via is formed in the via. The conductive via 43 is not only partially filled with the metal material, but also fully filled therewith. The conductive via 43 can electrically connect every circuit layer 42, or electrically connect to the outer circuit layer 341 in the semiconductor packaging substrate structure with a capacitor embedded therein. The dielectric layer 41 can be selected from photoimagable or photo-insensitive resin such as Ajinomoto build-up film (ABF), benzocyclobutene (BCB), liquid crystal polymer (LCP), polyimide (PI), poly(phenylene ether) (PPE), poly(tetrafluoroethylene) (PTFE), FR4, FR5, bismaleimide triazine (BT), and aramide, or a mixture of epoxy resin and glass fiber. For example, ABF can be used in the present example. A solder mask 45 is formed on the outermost surface of the built-up structure 40. The solder mask 45 has a plurality of openings 451 exposing portions of the built-up structure 40 serving as conductive pads 44. If necessary in the manufacture, the built-up structure 40 can be a single-layered or multi-layered structure.

Furthermore, as shown in FIG. 4B, a solder ball 46 can be formed in each of the openings 451 of the solder mask 45 on the surface of the built-up structure so as to electrically connect to a chip (not shown in FIG. 4B).

### EXAMPLE 4

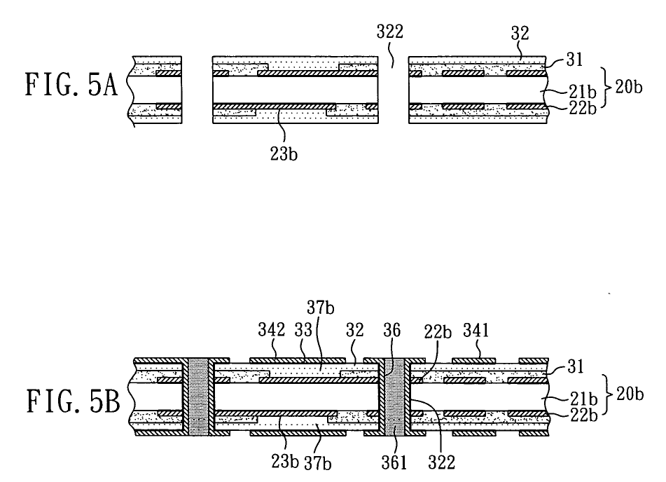

With reference to FIGS. 5A and 5B, there is a process of manufacturing the semiconductor packaging substrate structure with a capacitor embedded therein. The present example is substantially similar to Example 1, except an external plated through hole is formed to electrically connect the outer circuit layer and the inner circuit layer.

In FIG. 5A, an inner circuit board 20a is also provided first in the present example. The inner circuit board 20a is made by formation of an inner circuit layer 22b and an inner electrode layer 23b on the surface of a core board 21b. Other following steps are performed in the same manner as Example 1. After the high dielectric material layer 32 is formed, the whole structure is perforated by mechanical drilling to form a through hole 322. Subsequently, the seed layer 33 and the metal layer 34 are formed, and then etched to pattern the metal layer 34 as shown in FIG. 2D. Alternatively, the resist layer 35 is patterned, and then the circuits are formed as shown in FIG. 2D′. Therefore, the structure with a capacitor 37b embedded therein is completed in FIG. 5B. Besides the outer circuit layer 341 and the outer electrode layer 342 formed in the structure, an external plated through hole 36 is formed in the through hole 322. The external plated through hole 36 has a metal material layer formed on the inner surface thereof, and is filled with insulating resin 361. In regard to the semiconductor packaging substrate structure with a capacitor embedded therein of the present example, the external plated through hole 36 is used to electrically connect the outer circuit layer 341 on each of the surfaces of the semiconductor packaging substrate to the inner circuit layer 22b of the inner circuit board 20b.

### EXAMPLE 5

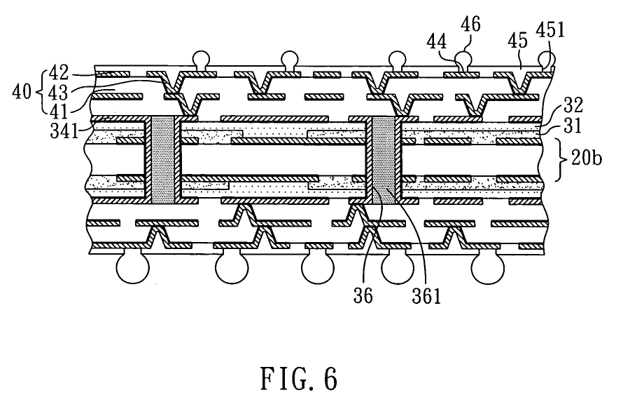

With reference to FIG. 6, a built-up structure 40 is formed on the surface of the semiconductor packaging substrate structure with a capacitor embedded therein manufactured in Example 4. The built-up structure 40 can be formed in the same manner as Example 3. The semiconductor packaging substrate structure connected with a chip is finally obtained.

With reference to FIGS. 2 to 6, the capacitors all are formed on the double-layered inner circuit board in the above-mentioned examples of the present invention. However, those are only for illustration. Actually, the used inner circuit board can be a double-layered or multi-layered circuit board. In addition, the capacitor can be embedded in any layer of the inner circuit board. The capacitor is not limited to a single-layered capacitor, and can be a multi-layered capacitor.

In conclusion, since the buffer layer is formed in the semiconductor packaging substrate structure of the present invention, the adhesion of the inner circuit layer or the inner electrode layer can be improved. Additionally, the gap between the circuits can be filled with a buffer layer made of photoimagable resin beforehand so that problems such as the insufficient amount of binder in the high dielectric material layer and the excessively low thickness thereof can be solved. Moreover, the lowered parasitic capacitance and the decrease of circuit leakage can be achieved between the high dielectric material layer and the area of the circuit layer not defined as a capacitor. The structure of the present invention can reduce the loss of signaling, enlarge the rate of signal transmission, and promote the quality of products. Besides, the present invention uses photolithography (including exposure and development) to pattern the buffer layer so that the area of the capacitor can be particularly defined. Therefore, the accuracy of the capacitor area can be advanced.

Although the present invention has been explained in relation to its preferred embodiment, it is to be understood that many other possible modifications and variations can be made without departing from the scope of the invention as hereinafter claimed.

What is claimed is:

1. A semiconductor packaging substrate structure with a capacitor embedded therein, comprising:
an inner circuit board having an inner circuit layer;
a patterned buffer layer disposed on at least one surface of the inner circuit board, wherein the portion of the inner circuit layer exposed by the patterned buffer layer serves as an inner electrode layer;
a high dielectric material layer located on the surfaces of the inner circuit board and the patterned buffer layer; and
a patterned metal layer placed on the surface of the high dielectric material layer, which comprises an outer circuit layer and an outer electrode layer, wherein the outer circuit layer electrically connects to the inner circuit layer of the inner circuit board, and the outer electrode layer locates corresponding to the inner electrode layer to form a capacitor.

2. The semiconductor packaging substrate structure with a capacitor embedded therein as claimed in claim 1, further comprising at least one conductive via formed in the high dielectric material layer to electrically connect the outer circuit layer to the inner circuit layer.

3. The semiconductor packaging substrate structure with a capacitor embedded therein as claimed in claim 1, further comprising an external plated through hole electrically connecting the inner circuit layer to the outer circuit layer which is disposed on the surface of the high dielectric material layer formed on each of the surfaces of the inner circuit board.

4. The semiconductor packaging substrate structure with a capacitor embedded therein as claimed in claim 1, wherein the inner circuit board further comprises an internal plated through hole.

5. The semiconductor packaging substrate structure with a capacitor embedded therein as claimed in claim 1, wherein the patterned buffer layer is photoimagable resin.

6. The semiconductor packaging substrate structure with a capacitor embedded therein as claimed in claim 1, wherein the high dielectric material layer is composed of polymer material, ceramic material, polymer material filled with ceramic powders, or a mixture of the like thereof.

7. The semiconductor packaging substrate structure with a capacitor embedded therein as claimed in claim 1, wherein the high dielectric material layer is formed by dispersing a material selected from the group consisting of barium titanate, lead zicronate tianate, and amorphous hydrogenated carbon into a binder.

8. The semiconductor packaging substrate structure with a capacitor embedded therein as claimed in claim 1, wherein the high dielectric material layer has a dielectric constant in a range of from 40 to 300.

9. The semiconductor packaging substrate structure with a capacitor embedded therein as claimed in claim 1, further comprising a built-up structure disposed on the surface of the outer circuit layer.

10. The semiconductor packaging substrate structure with a capacitor embedded therein as claimed in claim 1, further comprising a solder mask located on the surface of the built-up structure to protect the semiconductor packaging substrate structure.

11. The semiconductor packaging substrate structure with a capacitor embedded therein as claimed in claim 1, where the inner circuit board is a double-layered or multi-layered circuit board.

12. The semiconductor packaging substrate structure with a capacitor embedded therein as claimed in claim 11, wherein the inner circuit layer further comprises a plurality of capacitors.
